(19) United States
(12) Patent Application Publication
(10) Pub. No.: US 2020/0349528 A1
(43) Pub. Date: Nov. 5, 2020

(54) SYSTEM AND METHOD FOR DETERMINING A PROPERTY REMODELING PLAN USING MACHINE VISION

(71) Applicant: Stoa USA, Inc, North Miami Beach, FL (US)

(72) Inventor: Or AGASSI, Tel Aviv (IL)

(73) Assignee: Stoa USA, Inc, North Miami Beach, FL (US)

(21) Appl. No.: 16/863,569

(22) Filed: Apr. 30, 2020

Related U.S. Application Data
(60) Provisional application No. 62/841,357, filed on May 1, 2019.

(51) Int. Cl. G06Q 10/00; G06N 20/00; G06Q 50/16; G06F 30/13; G06K 9/00

(52) U.S. Cl. CPC G06Q 10/20; G06N 20/00; G06K 9/00684; G06F 30/13; G06Q 50/165

(57) ABSTRACT

A system and method for determining a property remodeling plan are provided. The method includes analyzing a received image stream demonstrating a real-estate property to identify at least one potential repair; classifying each of the least one identified potential repairs as at least one of a required repair and a recommended repair; and generating a property remodeling plan to address at least an identified potential repair.

### CROSS-REFERENCE TO RELATED APPLICATIONS

This application claims the benefit of U.S. Provisional Application No. 62/841,357 filed on May 1, 2019, the contents of which are hereby incorporated by reference.

### TECHNICAL FIELD

The present disclosure relates generally to computer vision and, more specifically, to real estate assessment based on results of machine vision analysis.

### BACKGROUND

Advances in computer technology continue to revolutionize longstanding areas of business. While automated production lines replace human operators and electronic systems provide for enhanced safety, efficiency, and accuracy across many fields, the building trades continue to rely on manual labor. In particular, the identification and remediation of building issues in real estate presents a significant need for human involvement. The use of manual labor in real-estate refurbishment generates high costs and requires time and patience to repair any defects in a building.

Many real-estate properties are owned by refurbishment organizations. These groups aim to improve the value of a property by making necessary repairs and, subsequently, selling the property for profit. In addition to the costs associated with implementing the needed repairs, the refurbishment process requires other costs, many of which may not be evident to the outside observer.

In order to generate a remodeling plan, refurbishment groups may hire a home inspector, typically a certified professional, to identify which repairs to a property may be needed. While inspection allows property owners to identify the repairs needed to improve a property's value, the cost of such inspections may reduce the profit available after restoration is completed. Further, the process of inspecting a property with a human inspector may be labor-intensive, requiring a non-negligible outlay of time and expense, which may reduce an owner's potential upside. In addition, appraisal reports often do not provide the full scope of information necessary to inform a repair decision, requiring separate appraisals to determine the costs associated with the repairs identified, as well as optimal renovation plans.

It would, therefore, be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for determining a property remodeling plan. The method comprises: analyzing a received image stream demonstrating a real-estate property to identify at least one potential repair; classifying each of the at least one identified potential repair as at least one of a required repair and a recommended repair; and generating a property remodeling plan to address at least an identified potential repair.

Certain embodiments disclosed herein also include a non-transitory computer readable medium having stored thereon instructions for causing a processing circuitry to execute a process, the process comprising: analyzing a received image stream demonstrating a real-estate property to identify at least one potential repair; classifying each of the at least one identified potential repair as at least one of a required repair and a recommended repair; and generating a property remodeling plan to address at least an identified potential repair.

Certain embodiments disclosed herein also include a system for determining a property remodeling plan. The system comprises: a processing circuitry; and a memory, the memory containing instructions that, when executed by the processing circuitry, configure the system to: analyze a received image stream demonstrating a real-estate property to identify at least one potential repair; classify each of the at least one identified potential repair as at least one of a required repair and a recommended repair; and generate a property remodeling plan to address at least an identified potential repair.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is an example network diagram utilized to describe the various embodiments disclosed.

FIG. 2 is an example flowchart describing a method for determining a value contribution of fixes performed throughout a property refurbishment process to the property sale price, according to an embodiment.

FIG. 3 is an example schematic diagram of an analytic engine for generating a remodeling plan, according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The various disclosed embodiments include a method and system for determining a property remodeling plan using machine vision. As inspection by human experts and subsequent logistical efforts may incur significant expense and set an owner behind schedule, reducing these manual inspections may help property owners to more effectively repair their properties. The disclosed system and method for determining a remodeling plan address these concerns, providing support for repair identification and evaluation, as well as project management planning.

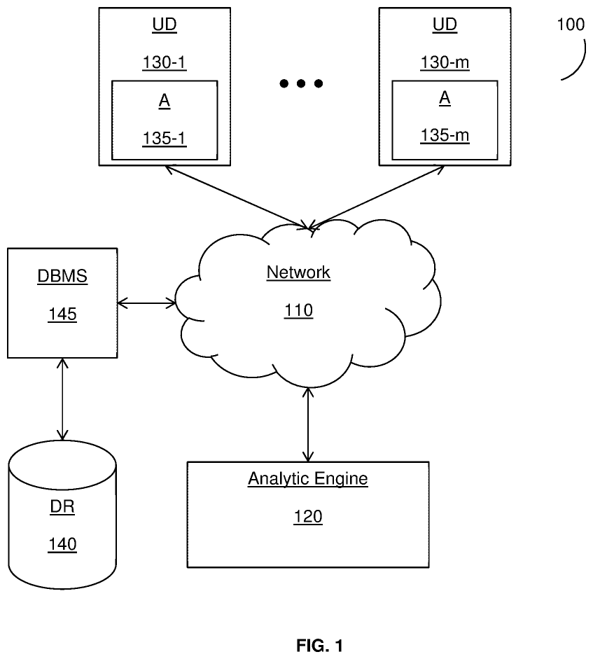

FIG. 1 is an example network diagram 100 utilized to describe the various embodiments disclosed. The example network diagram includes a network 110, an analytic engine 120, and one or more user devices, 130-1 through 130-m, each including one or more applications, 135-1 through 135-m. The network diagram 100 further depicts a data repository (DR) 140, connected to the network 110 through a database management service (DBMS) 145.

A network 110 is may be used to provide communication between different parts of the system depicted in the diagram 100. The network 110 may be the Internet, the world-wide-web (WWW), a local area network (LAN), a wide area network (WAN), a metro area network (MAN), or another network capable of enabling communication between the elements of the system depicted in the diagram 100. The network 110 may be configured to enable communication between the various elements depicted in the diagram 100. The network 110 may be a full-physical network, wherein all of the included components are implemented as physical devices. Further, the network 110 may be implemented as a virtual network, wherein the included components are simulated or otherwise virtualized. In addition, the network may be implemented as a hybrid physical-virtual network including some physical and some virtual components. The network 110 may be configured to connect various components using wired connections, such as Universal Serial Bus (USB), ethernet, and the like, using wireless connections, such as WiFi, Bluetooth™, Long-Term Evolution (LTE), and the like, or using various combinations of wired and wireless connections. Further, the network may be configured to encrypt data, both at rest and in motion, and to allow the transmission and receipt of encrypted, partially-encrypted, and unencrypted data.

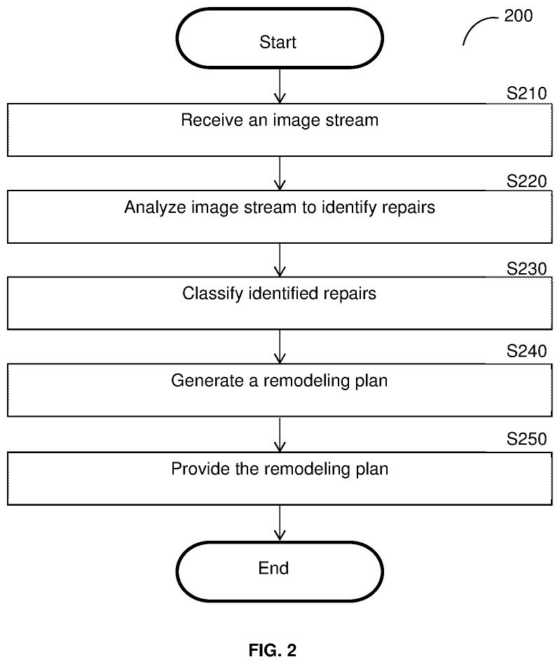

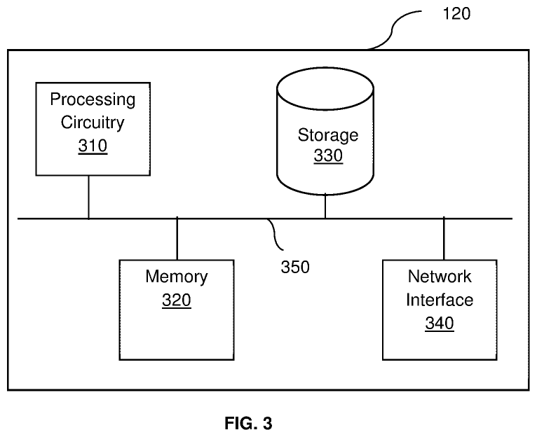

An analytic engine 120 is communicatively connected to the network 110. The analytic engine 120 and its components are described herein and in greater detail with respect to FIG. 3, below. The analytic engine 120 may be configured to execute one or more processes, including those processes described with respect to FIG. 2, below. The analytic engine 120 may be a personal or business computer, a cloud system, a server, or any other analytic engine. The analytic engine 120 may be connected to the network 110 by wireless means, wired means, or a combination of wired and wireless means. The analytic engine 120 may be configured to encrypt data and to store, send, and receive encrypted, unencrypted, and partially-encrypted data. The analytic engine 120 may be configured to receive data from various other devices or components via the network 110, to send data to various other devices or components via the network 110, or to both send and receive data, including simultaneously.

Optionally, one or more user devices 130-1 through 130-m, referred to individually as user device 130 and collectively as user devices 130, may be communicatively connected to the analytic engine 120 via the network 110. A user device 130 may be, for example, a smart phone, a mobile phone, a laptop, a tablet computer, a wearable device, a personal computer (PC), a smart television, or another wired or mobile appliance equipped with browsing, viewing, capturing, storing, listening, filtering, and managing capabilities enabled as further discussed below. The user device or user devices 130 may connect with the network 110 via wired means including, but not limited to, Universal Serial Bus (USB), ethernet, and the like, by wireless means such as WiFi, Bluetooth™, Long-Term Evolution (LTE), and the like, or by various combinations of wireless and wired means. Further, the connection between a user device 130 and the network 110 may be encrypted, partially-encrypted, or unencrypted. The connection between the user device or user devices 130 and the network 110 may be configured to allow the user device or user devices 130 to send data to the network 110, to receive data from the network 110, or to simultaneously send and receive data.

The user device 130 may be configured to send to, and receive from, the analytic engine 120, image streams, data, metadata, datasets, and the like which relate to, for example, a first property, a second property, a purchase price, a sale price, characteristics of fixes made throughout a refurbishment of each property, and so on. Further, the user device or user devices 130 may be configured to generate one or more image streams (video, photos, etc.) using features of the user device or user devices 130 such as, as examples and without limitation, cameras, microphones, keypads, touchscreens, accelerometers, other, like, features, and various combinations thereof.

Each user device 130 may further include a software application (App) 135 installed thereon. An application 135 may be downloaded from an application repository, such as the App Store®, Google Play®, or any other repository hosting software applications. The application 135 may be pre-installed on the user device 130. In an embodiment, the application 135 may be a web-browser. The application 135 may be configured to implement a process for generating remodeling plans. In an embodiment, the application 135 may be configured to generate a connection between one or more user devices 130 and one or more analytic engines 120, database management services 145, data repositories 140, and any combination thereof. In a further embodiment, the application 135 may be configured to generate a connection between multiple user devices 130 via the network 110.

It should be noted that only one user device 130 and one application 135 are shown in FIG. 1 merely for the sake of simplicity. However, the embodiments disclosed herein are applicable to a plurality of user devices 130 that can communicate with the analytic engine 120 via the network 110. Further, in an embodiment, the network 110 may be configured to enable connections between multiple user devices 130 without the inclusion of an analytic engine 120, and between multiple analytic engines 120 without the inclusion of a user device 130. The embodiments described may be implemented without any loss of generality or departure from the scope of the disclosed.

The data repository 140 may be communicatively connected with the analytic engine 120 via the network 110, or, in an embodiment, embedded within the analytic engine 120. The data repository 140 may be, for example, a storage device containing thereon a database, a data warehouse, or other, like, data storage implementations. The data repository 140 may be used for storing data including, without limitation, datasets, metadata, and the like, associated with properties' purchase price, properties' sale price, metadata associated with properties, datasets associated with fixes made throughout the processes of refurbishing properties (e.g., the cost of each objective), and other, like, aspects of the property remodeling process.

The data repository 140 may be configured to upload data to various components and devices via the network 110 and the database management service (DBMS) 145, to download or receive data from various components and devices via the network 110 and the database management service (DBMS) 145, or to both send and receive data. Further, the data repository 140 may be configured to encrypt stored data and to store encrypted data, unencrypted data, or partially-encrypted data. The data repository 140 may include duplicate data, parity data, or otherwise redundant data to ensure service continuity of the data repository 140. The data repository 140 may be connected with the DBMS 145 by wired means (such as ethernet, USB, and the like), by wireless means, such as by WiFi, Bluetooth™, LTE, and the like), or by a combination of wired and wireless means.

The data repository 140 may be communicatively connected to the network 110 through the DBMS 145. The DBMS 145 may be configured to provide data-retrieval instructions, data storage rules, storage optimizations, and other storage-related instructions to the data repository 140. The DBMS 145 may be further configured to serve as an intermediary between the data repository 140 and the network 110, allowing various components and devices connected to the network 110 to send data to, and receive data from, the data repository 140. Where the DBMS 145 is configured to serve as such an intermediary, the DBMS 145 may be configured to parse received database requests into a format suitable for data repository 140 manipulation, such as, as an example and without limitation, an SQL request. The DBMS 145 may be further configured to provide information regarding the data repository 140 including, without limitation, available remaining storage space, estimated data transfer times and speeds, other, like, information, and any combination thereof. The DBMS 145 may be configured to connect with the network 110 by wired means, by wireless means, or by a combination of wired and wireless means.

Although a single DBMS 145 and a single data repository 140 are depicted in FIG. 1 for simplicity, multiple of each or both components may be deployed without any departure from the scope of the disclosed embodiments or any loss of generality. The multiple database management services 145, data repositories 140, or both, may be co-located, or may be dispersed across multiple locations. One or more of the database management services 145, data repositories 140, or both, may be physical components, virtual components, or hybrid components, including both physical and virtual elements.

In an embodiment, the analytic engine 120 may be configured to receive one or more image streams for at least one portion of a first real-estate property. The first real-estate property may be, for example, a house, an office, a shop, an apartment, and so on. The one or more image streams show the first property and may be, but are not limited to, images, photos, videos, or portions thereof. The image streams may be received from a user device, such as the user device 130. The image streams may be captured by the user device 130, such as with an included camera. Further, the image streams may be captured by another device and transferred to the user device 130, such as through a file download, a data transfer, and the like. The image streams may include one or more features depicting aspects of the property including color, depth, motion, reflectivity, and the like. An image stream may be a single, standalone element, or one of many image streams created as a set. The image streams may include one or more tags describing aspects of the property, aspects of the potential repair, or both. The image or streams may further include metadata describing aspects of the image stream or streams including, without limitation, the type of device on which the image or streams were captured, the date on which the image stream or streams were captured, relevant geotagging data, other, like, aspects, and any combination thereof. In an embodiment, the image stream or streams may include depictions of a property, or aspects of a property, from various angles.

The first image stream or streams are analyzed using one or more machine vision techniques. The machine vision techniques applied to analyze the image stream or streams may be applied to generate a computer-readable model. The analytic engine 120 may generate a computer-readable model from the image stream or streams based on factors including, without limitation, geometry, placement, color, reflectivity, texture, material, and the like. The generation of a computer-readable model from the received image stream or streams is described in greater detail with respect to FIG. 2, below. In an embodiment, the machine vision techniques applied may include the generation of signatures based on the image stream or streams. Signatures may be generated during the analysis. The generated signatures may then be compared to a plurality of similar signatures by a plurality of methods such as, for example, mapping a signature vector representation into a vector space and using the Euclidean distance between vectors as the first approximation of the difference between the compared vectors. Such a comparison may be made more efficient by applying embedding algorithms which reduce the number of dimensions in the vector space. The generation and comparison of signatures is further described with respect to FIG. 2.

The generated signatures are analyzed to identify one or more potential repairs applicable to the property. applicable repairs may be detected based on the inclusion of signatures assigned to discontinuous or disjoint features. It may be noted that, as potential repairs applicable to a property may present as visible discontinuities, potential repairs may be identified by determining those points at which features cease to be continuous. Where the generated computer-readable model includes features separated by one or more discontinuities, such as corners, cracks, and holes, the visible discontinuities may be associated with signatures describing the location, geometry, color, and other, like, attributes of the discontinuity. Signatures generated based on these discontinuities may be reviewed, either manually or automatically, as described in greater detail with respect to S220 of FIG. 2, below. Based on the review, the discontinuities may be confirmed as potential repairs, flagged for further review, or discarded, as necessary.

According to another embodiment, the analysis includes a clustering phase, in which the image stream or streams are clustered to groups. The inclusion of a clustering phase may allow for the identification of construction objects or potential repairs for which multiple image streams are available, for the identification of potential repairs which may require similar or identical fixes, and other improvements allowed by the grouping of error data based on similarity. The clustering of image streams into groups is described in greater detail with respect to S220 of FIG. 2, below.

Based on the analysis, the analytic engine 120 may be configured to identify potential repair, applicable to the property and requiring a fix. As described below with respect to FIG. 2, one or more potential repairs may be identified based on the analysis, the signatures generated, any relevant clusters, and the like. The identified potential repairs may include visible problems with the property including, as examples and without limitation, cracks, holes, leaks, and the like. The identified potential repair or repairs may be marked with a label or tag within the computer-readable model, within the generated signature dataset, or both. Where multiple potential repairs are identified in a single image stream, the potential repairs may be labeled independently or together, and may be labeled according to a predetermined labeling scheme or rule.

A query is made to the data repository 140 to determine the fix needed in order to implement the potential repair or repairs determined based on the analysis of the image stream or streams. The fix may be identified by review of the analysis, the signatures generated therein, other, like, factors, or a combination thereof. The query, as applied in an embodiment, is described in greater detail with respect to FIG. 2, below.

The query may include information describing the property, information describing the potential repair or repairs, and the like. The information describing the property may include, without limitation, the year the property was constructed, a relevant fix history, and the like. The information relevant to the property may be gathered from sources including, without limitation, public records, the property owner's files, a combination thereof, and the like.

The information describing the potential repair or repairs may include, as examples and without limitation, the size of the potential repair, the material in which the potential repair occurred, special conditions requiring particular attention, and the like. The query may further specify relevant constraints such as, as examples and without limitation, the property owner's budget, the project timeframe, and the like.

The fix may include one or more instructions, processes, labor specifications, or the like. Further, the fix may include a list of materials, a time estimate, a cost estimate, and the like. The fix may be determined by comparing the potential repair identified in the query with a list of similar or identical repairs stored in the data repository 140. The fix may include an overall confidence estimate, describing the degree to which an identified fix matches the potential repair specified in the query. Further, the fix may include element-specific confidence estimates, describing the degree to which the various elements of the fix correspond with the potential repair specified in the query. Further, the fix may be manually overridden by user or administrator input. In an embodiment, where a user or administrator overrides some or all aspects of a fix, the fix may include a label indicating which aspects of the fix are automatically-generated and which aspects are the result of manual override.

In an embodiment, the analytic engine 120 may be configured to gather a dataset that includes a plurality of fixes relevant to a second property having similar characteristics in a remodeling process. The plurality of fixes made in the remodeling process may include, for example and without limitation, rehabilitation, replacement, demolition, cleaning, painting, installation of new appliances, and the like. The dataset may include a first set of metadata related to the plurality of fixes. The first set of metadata may indicate, for example, the cost of each of the plurality of fixes, where each product or service associated with the plurality of fixes was purchased (e.g., a vendor from which each product or service was purchased), and the like. The gathered dataset may include fixes and metadata drawn from a data store, such as the data repository 140. In an embodiment, the analytic engine 120 may be configured to train a machine learning model using the contents of the gathered dataset. The training of the machine learning model may include the generation of a ruleset, based on the contents of the dataset relevant to a second property, where the ruleset may include rules which configure the analytic engine 120 to select specific fixes for identified potential repairs. In an embodiment, the machine learning model may be applied to the automatic selection of fixes based on potential repairs identified in one or more received image streams, wherein the identification of potential repairs in the received image streams is further described with respect to FIG. 2, below.

FIG. 2 is an example flowchart 200 describing a method for determining a value contribution of fixes performed throughout a property refurbishment process to the property sale price, according to an embodiment. In an embodiment, the method described herein below may be executed by the analytic engine 120 that is further discussed with respect to FIG. 3, below.

At S210, at least one image stream is received. The at least one image stream demonstrates a real estate property, or a portion thereof, and may include at least one identifiable potential repair. Each image stream may include, for example, a video clip, an image, a portion thereof, or the like. In the image stream, at least an interior view or an exterior view of the real-estate property is shown. The received image stream may be generated by a user device, such as the user device, 130, of FIG. 1, above, for example. The contents of the image stream may be one or more photographs or videos taken or recorded using a camera included in the user device. The contents of the one or more image streams may be generated by a different device, including at a previous time, and may be saved, streamed, or otherwise included as a transmissible data element in the user device. In an embodiment, the image stream or image streams may be received from a device, other than the user device, 130, of FIG. 1, above, including, without limitation, a camera installed in the real estate property.

In an embodiment, S210 further includes receiving a dataset that is associated with the real estate property. The dataset may include a purchase price of the property, a location of the property, and the like. Data included in the dataset may be formatted as strings, characters, numbers, dates, and the like. Data included in the dataset may be drawn from sources including, without limitation, searches of public records and webpages, cached data stored in a data repository, user inputs, a combination thereof, and the like. The dataset may include indicators specifying whether one or more data entries includes a contested, estimated, or unknown value. Further, the dataset may include one or more confidence ratings associated with data entries including unknown, estimated, or contested values.

At S220, the at least one image stream is analyzed to generate a computer-readable model and to identify at least one potential repair, based on the received at least one image stream. In an embodiment, S220 includes analyzing, using machine vision techniques, the contents of the one or more image streams received at S210 to identify one or more construction objects in, and potential repairs applicable to, the property, as depicted in the one or more image streams. In an additional embodiment, analyzing at least one image stream at S220 may include identification of construction objects in the image stream. Construction objects may include structural features such as walls and supports, cosmetic features, such as countertops and wallpaper, appliances, such as dishwashers and microwaves, and other, like, features. Further, analysis at S220 may, in an embodiment, include generating a remodeling plan including at least one fix, as is described with respect to S240, below.

The contents of the image stream or image streams may be analyzed to generate a computer-readable model using techniques including machine vision. Where the image stream or streams include at least one video or photo, features including geometry, color, texture, reflectivity, movement, and the like may be extracted from the contents of the image stream or streams. The extraction of such data features from the image stream or streams may allow for the representation of a room, area, or element of the property in three dimensions, whether as a visual model or in a pure-data format. The representation of such rooms, areas, and elements may be achieved using techniques including, without limitation, analysis of geometry by determining the dimensions of a construction object using an included object for scale, determination of feature dimensions using angle differences between multiple cameras and multiple photos or videos, other, like, techniques, or a combination thereof.

In addition, the contents of the image stream or streams may be analyzed to extract non-geometric feature information such as color, texture, and reflectivity. Where the color, texture, or reflectivity of a depicted construction object appear in the received image stream or streams, the material comprising the depicted construction object may be determined by comparison with a database of various materials' visual characteristics. In an embodiment, the data repository, 140, of FIG. 1, above, may be configured to provide material classification for image stream analysis.

In an embodiment, analysis at S220 may include matching identified construction objects with the respective objects' standard states. The respective objects' standard states may be determined by collecting standard state data for a plurality of construction objects. Standard state data may be collected from sources including, without limitation, the data repository, 140, of FIG. 1, above. Construction object standard states may include states wherein a construction object is in compliance with one or more predetermined guidelines including, without limitation, building codes. Construction objects may be compared against the respective objects' standard states by analysis of aspects of the construction objects including, without limitation, the associated image stream or streams, relevant metadata, associated signatures, as described below, other, like aspects, and any combination thereof. As described with respect to S230, below, construction objects which do not meet their respective standard states may be subsequently classified as required repairs. In a further embodiment, analysis at S220 may include application of a machine learning process to automatically identify construction objects and match the identified construction objects to the respective objects' standard states.

In an embodiment, analysis at S220 may include matching identified construction objects with the respective objects' current architectural specifications. The respective objects' current architectural specifications may be determined by collecting current architectural specification data for a plurality of construction objects. Current architectural specification data may be collected from sources including, without limitation, the data repository, 140, of FIG. 1, above. Construction objects may be compared against the respective objects' current architectural specifications by analysis of aspects of the construction objects including the associated image stream or streams, relevant metadata, associated signatures, as described below, other, like aspects, and any combination thereof. As described with respect to S230, below, construction objects which do not match their respective current architectural specifications may be subsequently classified as recommended repairs. In a further embodiment, analysis at S220 may include application of a machine learning process to automatically identify construction objects and match the identified construction objects to the respective objects' current architectural specifications.

In an embodiment, S220 includes generating signatures identifying particular construction objects or potential repairs in a given area, room, or property. Recommended or required repairs within a property may present as visual discontinuities, such as in the case of cracks, holes, misalignments, and the like. As a result, the generation of signatures on detection of discontinuities may provide for subsequent repair identification. Signatures may be generated for unique construction objects, where each unique construction object includes some element of difference from neighboring construction objects, either in geometry, color, reflectivity, texture, motion, or the like.

Signatures may be included in the generated computer-readable model or may be included in a related signature-tracking file, wherein the various signatures may be mapped to their respective elements in the computer-readable model. Signatures may be compared with one or more similar signatures to identify commonalities or differences, allowing for the identification of continuous recommended or required repairs, such as long cracks, as well as subsequent improvements in fix-suggestion efficiency.

Signatures may be compared using methods including vector mapping, whereby a signature's vector representation may be mapped to a vector space, allowing for the identification of differences between signature vectors using Euclidian distance. The vector mapping method may be enhanced by the application of embedding algorithms for dimensionality reduction.

The generated signatures may be analyzed, and, based on the analysis, a computer readable structured model may be generated. In an embodiment, the analysis may include matching one or more image streams to the contents of a data warehouse, accessible via a web source, based on factors including, but not limited to, image stream contents, image stream metadata, individual signatures, clusters of signatures, and the like, as well as any combination thereof. The generation of a computer-readable structured model from the signatures may include mapping the various signatures with respect to one another in a three-dimensional space. Signatures may be positioned relative to one another based on factors such as, without limitation, the height, width, and depth of the features corresponding to the respective signatures. Further, signatures mapped with respect to one another in a three-dimensional space may be separated and identified by attributes included in the respective signatures based on the corresponding features' color, reflectivity, texture, material, and the like. In an embodiment, the signatures may be aggregated and mapped within a virtual space. In a further embodiment, discontinuities may be identified between features based on differences within the contents of the signatures. Such a signature mapping process may allow for the representation of distinct, discontinuous construction objects, as represented by the signatures corresponding to the discontinuous construction objects. Further, signature mapping may provide for the representation of continuous construction objects, such as intact walls, as may be generated inferentially. Continuous construction objects may be represented by inference by comparing two neighboring signatures and determining that the signatures share one or more common aspects which may indicate the character of the space between the construction objects associated with the signatures. In an example, two neighboring signatures, each corresponding with respective cracks in a wall, may include information specifying a white color and a plaster material. Based on this information, the region between the cracks corresponding with the signatures may be determined to be intact, white, plaster.

The generated computer-readable model may be a three-dimensional visual model describing the entire property, the specified construction object, room, or area, other, like, aspects of the property, or only the error identified. Where a three-dimensional model is generated, the model may include representations of qualities of the property including, without limitation, depth, height, width, color, reflectivity, movement, texture, other, like, qualities, and any combination thereof. The model may be configured to render on a display, such as a display included in the one or more analytic engines 120, the one or more user devices 130, both of FIG. 1, above, other, like, devices, and any combination thereof. In an embodiment, the three-dimensional visual model may be generated in one or more standard three-dimensional model filetypes such as, as an example and without limitation, a .STL file.

In a further embodiment, the generated computer-readable model may be a data map or other non-graphical representation of the contents of the image stream or streams, such as the property, the specified construction object, room, or area, or the identified potential repair. Where a non-graphical model is employed, the model may, as above, include data representations of qualities of the property including, without limitation, depth, height, width, color, reflectivity, movement, texture, other, like, features, and any combination thereof.

In an embodiment, the analysis at S220 may further include a clustering phase, in which a plurality of image streams, or the contents thereof, are clustered to groups. The groups may be clustered, for example, based on metadata associated with the image streams or image stream contents. The analytic engine 120 may generate a score for each cluster. The score generated may indicate the probability that a cluster includes a certain recommended or required repair. The score may be based on the metadata associated with each image stream, or the contents of each image stream, included in the cluster. The metadata may include characteristics of the real estate property such as, for example, type, location, structural characteristics, size, and the like. Image streams, and image stream contents, may be clustered based on pre-defined rules or may be clustered based on the degree of similarity of the image streams' associated metadata. In an embodiment, the image stream clustering may be reviewed manually, and image streams, and image stream contents, may be removed from clusters, assigned to other clusters, or specified as new clusters, based on operator or administrator input.

In an embodiment, the score generated for each cluster may be based on the number of image streams, or image stream content elements, included in the cluster, the metadata associated with the image streams or image stream contents, or both. In an embodiment, the score may be generated as a weighted average, wherein the various metadata categories may be assigned weighting values based on the importance of each category to the clusters generated. The clusters may be based on one or more central image streams, or the contents thereof, to which additional image streams, and the respective contents, may be compared. The differences between the values of the image stream metadata may, in an embodiment, be calculated by converting the metadata attributes into vectors and comparing the respective vectors for multiple image streams or image stream content elements, such as by Euclidian distance measurement, to determine difference values. The determined difference values, indicating the similarity of the various metadata attributes of two image streams or image stream content elements, may be averaged using the weighting values assigned previously to determine the overall weighted average similarity of two image streams or image stream content elements. Image streams and image stream content elements may be clustered according to weighted averages.

Clusters may be generated according to pre-defined rules, allowing for the generation of clusters including elements with specific similarities. Examples of predefined rules may include rules specifying that all image streams within a cluster must have a certain minimum weighted average similarity score, rules specifying that all image streams within a cluster must contain a metadata element having a predetermined value, rules specifying that the first five image streams received may be included in the cluster, a combination thereof, and the like. Further, image streams may be manually clustered, either by a user or by an image stream analysis expert, for example, in order to identify outlying image streams or image stream content elements evading automatic clustering.

Further, at S220, at least one repair is identified. The identified repair may be construction object requiring fixing such as, for example, a mold issue, missing paint, broken tiles, and the like. The repairs may be identified based on the analysis at S220, the signatures generated therein, or any combination thereof. The repair or repairs may be identified by detecting image stream construction objects or signatures which are dissimilar from the surrounding construction objects or signatures, indicating a discontinuity which may be indicative of a recommended or required repair for the property. The repair or repairs may be identified automatically or may be a discontinuity flagged for manual review. In an example embodiment, analysis at S220 may further include comparing at least a first signature with at least a second signature to verify a discontinuity.

Where the repair or repairs are identified automatically, the repair or repairs may be flagged for remediation. The repair or repairs may be flagged for remediation by associating an error label with the section of the computer-readable model containing the recommended or required repair or repairs, by associating a repair label with the corresponding signature, or both. Error labels may include classifications, as described with respect to S230. In an embodiment, the repair or repairs may be categorized into one of several error types such as, as examples and without limitation, cracks, holes, leaks, misalignments, and the like.

Where the image stream or image streams include a construction object which may include a recommended or required repair but which is not automatically identified as such, the potential repair may be flagged for review. As noted above, potential repairs may be identified by detection of possibly-disjoint image stream construction objects or signatures, and, as above, may be flagged by assigning review labels to the section of the computer-readable model containing the potential repair, to the corresponding signature, or both. Where a potential repair requires manual review, the repair may be set aside or otherwise separated from automatically-identified repairs, pending human determination of whether the identified construction object includes a recommended or required repair. Where a human operator identifies a repair applicable to the property, the review label may be replaced with a repair label, marking the feature for remediation. Where no applicable repair is identified, the review tag may be discarded. In an embodiment, revised instructions or training data, reflecting the human determination of whether a feature includes an applicable repair, may be provided.

At S230, the potential repair or repairs identified during analysis at S220 are classified as either recommended repairs or required repairs. Repairs may be classified based on factors including, without limitation, the type of repair identified during analysis at S220, data or metadata features included in the associated signature or signatures or image stream or image streams, aspects of other, neighboring repairs or signatures, and other, like, factors. Repairs may be classified by collecting repair classification data from one or more sources including, without limitation, the data repository, 140, of FIG. 1, above. Repairs may be classified as recommended repairs or as required repairs. In an embodiment, repairs comprising property improvements implemented to bring an identified construction object into a state identified in a current architectural specification may be classified as recommended repairs. Recommended repairs may include replacement of outdated countertops, defective appliances, showerheads, and other, related, cosmetic features. Repairs including construction objects which do not match their standard state, as determined at S220, may be classified as required repairs. Further, repairs comprising property improvements implemented to address a home inspection issue may be classified as required repairs. Required repairs may include repairs necessary to overcome inspection issues, such as replacing structural beams, repairing leaking roofs, and the like. Where a repair includes both required and recommended elements, the repair may be subdivided into the required and recommended elements, and the required and recommended elements may be separately classified.

At S240, based on the at least one identified repair classified at S230, a remodeling plan is generated, wherein the remodeling plan addresses at least one potential repair and includes at least one fix. The remodeling plan may include one or more fixes extracted from the data repository, 140, of FIG. 1. Further, the remodeling plan may include fixes for multiple areas of a property, multiple properties at once, or both. Remodeling plans including multiple fixes, multiple properties, or both may be applicable to property owners seeking to consolidate service and maintenance bills. The remodeling plan may further include cost estimates, repair time estimates, material requirements, special requirements, such as a requirement that a tenant vacate a particular room, recommended contractors, other, like, information, and any combination thereof. In an embodiment, the remodeling plan generated at S240 may include a recommended fix for each recommended repair, as identified at S230, wherein the recommended fix is selected based on factors including, without limitation, a predefined budget. The remodeling plan may be stored, cached, or otherwise saved in the data repository, 140, the user device, 130, or the analytic engine, 120, of FIG. 1, above, and any combination thereof. The remodeling plan may be stored as a password-protected file and may be encrypted, partially encrypted, or unencrypted.

The generation of the remodeling plan at S240 may include the generation of a query, where the query is sent to a data repository (e.g., the data repository, 140, of FIG. 1) to extract data associated with at least one fix corresponding to at least one identified repair. The query may identify a particular construction object or fault describing the identified repair. Further, the query may include data describing the identified repair in greater detail, such as by describing the size, material, and other features of the identified repair. In addition, the query may include data describing repair-adjacent concerns, such as a special consideration for which a particular fix may be required, or the property owner's budget or time window. As an example, the information contained in a query may specify that the construction object including the identified repair is a ceiling, that the repair identified is a hole, that the identified repair material is drywall, and that the repair size is ten inches by ten inches. Further, in an example, the query may specify, as a special concern, that the property is insulated with asbestos.

The remodeling plan generated at S240 may include content types including, without limitation, images, videos, lists, charts, tables, text, other, like, content types, and any combination thereof. The various elements of the remodeling plan may be applied to develop detailed process instructions and cost and time estimates, including information relevant to one or more fixes included in the remodeling plan generated at S240. The remodeling plan may be generated according to a template, may be manually customized for individual property owners, or may be generated as a template and subsequently manually edited. In an embodiment, the remodeling plan may be edited, revised, or otherwise modified on the instruction of an authorized user, administrator, or overseer. Where a remodeling plan is manually modified, the remodeling plan may be configured to include indications of which aspects of the plan derive from machine analysis and which aspects derive from administrative override.

At S250, the remodeling plan is provided. In an embodiment, the remodeling plan may be provided as an output to the user device, 130, of FIG. 1, above. The remodeling plan may be provided in formats including, without limitation, as a text-based file, such as a .PDF or .DOC file, as a webpage available on a user device, 130, of FIG. 1, above, as a feature of the application, 135, of the user device, 130, both of FIG. 1, above, by other, like, means, or by any combination thereof. The remodeling plan may be provided via means including, without limitation, email, SMS, posted letter, in-application notification, and other, like, means.

FIG. 3 is an example schematic diagram of an analytic engine 120 for generating a remodeling plan, according to an embodiment. The analytic engine 120 includes a processing circuitry 310 coupled to a memory 320, a storage 330, and a network interface 340. In an embodiment, the components of the analytic engine 120 may be communicatively connected via a bus 350.

The processing circuitry 310 may be realized as one or more hardware logic components and circuits. For example, and without limitation, illustrative types of hardware logic components that can be used include field programmable gate arrays (FPGAs), application-specific integrated circuits (ASICs), application-specific standard products (ASSPs), system-on-a-chip systems (SOCs), general-purpose microprocessors, microcontrollers, digital signal processors (DSPs), and the like, or any other hardware logic components that can perform calculations or other manipulations of information.

The memory 320 may be volatile (e.g., RAM, etc.), non-volatile (e.g., ROM, flash memory, etc.), or a combination thereof. In one configuration, computer readable instructions to implement one or more embodiments disclosed herein may be stored in the storage 330.

In another embodiment, the memory 320 may be configured to store software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the processing circuitry 310, cause the processing circuitry 310 to perform the various processes described herein.

The storage 330 may be magnetic storage, optical storage, and the like, and may be realized, for example, as flash memory or another memory technology, CD-ROM, Digital Versatile Disks (DVDs), or any other medium which can be used to store the desired information.

The network interface 340 allows the analytic engine 120 to communicate with the network, 110, of FIG. 1, above, for the purpose of, for example, receiving data, sending data, and the like.

It should be understood that the embodiments described herein are not limited to the specific architecture illustrated in FIG. 3, and that other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform, such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for determining a property remodeling plan, comprising:
analyzing a received image stream demonstrating a real-estate property to identify at least one potential repair;
classifying each of the at least one identified potential repair as at least one of a required repair and a recommended repair; and
generating a property remodeling plan to address at least an identified potential repair.

2. The method of claim 1, wherein analyzing the received image stream further comprises:
identifying construction objects in the received image stream;
matching the identified objects to respective objects in their standard state; and
classifying identified construction objects that do not meet their standard state as a required repair.

3. The method of claim 2, further comprising:
applying a machine learning process to automatically identify construction objects and matching the identified construction objects to respective objects in their standard state.

4. The method of claim 2, wherein objects in their standard state at least comply with a building code.

5. The method of claim 4, wherein an identified required repair is considered a home inspection issue.

6. The method of claim 1, wherein the property remodeling plan further includes an identified recommend repair.

7. The method of claim 1, further comprising:
identifying construction objects in the received image stream;
matching the identified construction objects to respective objects in their current architectural specification; and
classifying identified construction objects that do not meet their current architectural specification as a recommend repair.

8. The method of claim 7, wherein the property remodeling plan includes a recommend fix for each recommend repair, wherein the recommend fix is selected based on at least a predefined budget.

9. The method of claim 8, further comprising:
applying a machine learning process to automatically identify construction objects and matching the identified objects to respective objects in their current architectural specification.

10. The method of claim 1, wherein the image stream is received from at least a camera installed in the real-estate property.

11. The method of claim 1, wherein analyzing the received image stream further includes:
generating a remodeling plan including at least one further fix.

12. The method of claim 11, further comprising:
providing the remodeling plan.

13. A non-transitory computer readable medium having stored thereon instructions for causing a processing circuitry to execute a process, the process comprising:
analyzing a received image stream demonstrating a real-estate property to identify at least one potential repair;
classifying each of the at least one identified potential repair as at least one of a required repair and a recommended repair; and
generating a property remodeling plan to address at least an identified potential repair.

14. A system for determining a property remodeling plan, comprising:
a processing circuitry; and
a memory, the memory containing instructions that, when executed by the processing circuitry, configure the system to:
analyze a received image stream demonstrating a real-estate property to identify at least one potential repair;
classify each of the at least one identified potential repair as at least one of a required repair and a recommended repair; and
generate a property remodeling plan to address at least an identified potential repair.

15. The system of claim 14, wherein the system is further configured to:
identify construction objects in the received image stream;
match the identified objects to respective objects in their standard state; and
classify identified construction objects that do not meet their standard state as a required repair.

16. The system of claim 15, wherein the system is further configured to:
apply a machine learning process to automatically identify construction objects and match the identified construction objects to respective objects in their standard state.

17. The system of claim 15, wherein objects in their standard state at least comply with a building code.

18. The system of claim 17, wherein an identified required repair is considered a home inspection issue.

19. The system of claim 14, wherein the property remodeling plan further includes an identified recommend repair.

20. The system of claim 14, wherein the system is further configured to:
identify construction objects in the received image stream;
match the identified construction objects to respective objects in their current architectural specification; and
classify identified construction objects that do not meet their current architectural specification as a recommend repair.

21. The system of claim 20, wherein the property remodeling plan includes a recommend fix for each recommend repair, wherein the recommend fix is selected based on at least a predefined budget.

22. The system of claim 21, wherein the system is further configured to:
apply a machine learning process to automatically identify construction objects and match the identified objects to respective objects in their current architectural specification.

23. The system of claim 14, wherein the image stream is received from at least a camera installed in the real-estate property.

24. The system of claim 14, wherein the system is further configured to:
generate a remodeling plan including at least one further fix.

25. The system of claim 24, wherein the system is further configured to:
provide the remodeling plan.
